(19) United States
(12) Patent Application Publication
(10) Pub. No.: US 2008/0073690 A1
(43) Pub. Date: Mar. 27, 2008

(54) Flash memory device including multilayer tunnel insulator and method of fabricating the same

(76) Inventors: Sung-kweon Baek, Suwon-si (KR); Sang-ryol Yang, Hwaseong-si (KR); Si-young Choi, Seongnam-si (KR); Bon-young Koo, Suwon-si (KR); Ki-hyun Hwang, Seongnam-si (KR); Dong-kak Lee, Seoul (KR)

Correspondence Address: LEE & MORSE, P.C., 3141 FAIRVIEW PARK DRIVE, SUITE 500, FALLS CHURCH, VA, 22042, US

(21) Appl. No.: 11/589,789

(22) Filed: Oct. 31, 2006

(30) Foreign Application Priority Data
Sep. 26, 2006 (KR) 10-2006-0093524

(51) Int. Cl. H01L 29/76

(52) U.S. Cl. 257/314

(57) ABSTRACT

A flash memory device may include a lower tunnel insulation layer disposed on a substrate, an upper tunnel insulation layer disposed on the lower tunnel insulation layer, a floating gate disposed on the upper tunnel insulation layer, an intergate insulation layer disposed on the floating gate; and a control gate disposed on the intergate insulation layer.

### BACKGROUND OF THE INVENTION

1. Field of the Invention

The present invention relates to a flash memory device. More particularly, the present invention relates to a flash memory device including a multilayer tunnel insulator, and a method of fabricating the same.

2. Description of the Related Art

One important element for evaluating properties of flash memory devices is a tunnel insulator. Tunnel insulators are insulation layers through which a considerable number of electrons tunnel when programming information to or erasing information from floating gates. Tunnel insulators are very important for evaluating properties of flash memory devices. Various characteristics of tunnel insulators should be evaluated. For example, the insulating properties, dielectric constant, thickness, flexibility, thermal stability, film composition and density, and, more importantly, compatibility of the tunnel insulator with relatively cheap and/or commonly adopted processes for fabricating typical semiconductor devices should be evaluated. Silicon oxide layers have been widely used as tunnel insulators because silicon oxide layers generally meet the aforementioned requirements associated with tunnel insulators, are widely used in semiconductor processes, and are relatively cheap.

However, as the integration density of flash memory devices increases, the film compositions and structures of flash memory devices have gradually changed. For example, conductive materials are increasingly being replaced by metallic materials, and structures of films that were previously formed of conductive materials are gradually changing. Various layers other than a silicon oxide layer and a silicon nitride layer are increasingly being used as insulation layers.

Theoretically, as the integration density of flash memory devices increases, the thickness of tunnel insulators should be gradually reduced accordingly. That is, as the integration density of flash memory devices increases, sizes of elements of flash memory devices should be reduced accordingly in order for flash memory devices to operate properly even with low power, and to guarantee stable programming, erasing, and information retention capabilities even at low voltages and low currents.

However, it is not easy to form thinly-structured tunnel insulators. From a manufacturing viewpoint, it is relatively difficult to form thin tunnel insulators. From an electrical viewpoint, when tunnel insulators are too thin, electrons stored in floating gates can easily pass through the tunnel insulators and, thus, are likely to leak from the tunnel insulators, thereby compromising image retention capabilities. Thus, a tunnel insulator should be formed so as ensure an appropriate electrical thickness.

It is difficult, however, for conventional tunnel insulators, formed of silicon oxide to meet the requirements of facilitating the tunneling of electrons and enable program and erase operations to be performed even at low voltages, and stabilizing information retention capabilities.

The properties of tunnel insulators can be improved by using methods that involve forming a thin insulation layer having high dielectric metal oxide such as hafnium oxide, aluminum oxide, titanium oxide, or tantalum oxide. However, these metal oxides are neither materials that are widely used in the fabrication of semiconductor devices nor materials that are common and plentiful. In addition, it is relatively unstable and costly to form tunnel insulators using these metal oxides. Moreover, tunnel insulators that include these metal oxides provide poor interfacial properties with silicon substrates or other conductive materials. Furthermore, tunnel insulators that include these metal oxides are vulnerable to heat and are, thus, generally difficult to apply to the fabrication of semiconductor devices.

### SUMMARY OF THE INVENTION

The present invention is therefore directed to a multilayer tunnel insulator employable in a flash memory device, and a method of fabricating such a multilayer tunnel insulator.

It is therefore a feature of embodiments of the present invention to provide a flash memory device including a multilayer tunnel insulator that may be programmed or erased at a low voltage, while having improved information retention capabilities relative to devices employing a conventional single layer tunnel insulator.

It is therefore a separate feature of embodiments of the present invention to provide a method of fabricating a flash memory device including a multilayer tunnel insulator that may be programmed or erased at a low voltage, while having improved information retention capabilities relative to devices employing a conventional single layer tunnel insulator.

At least one of the above and other features and advantages of the present invention may be realized by a flash memory device, including a lower tunnel insulation layer disposed on a substrate, an upper tunnel insulation layer disposed on the lower tunnel insulation layer, a floating gate disposed on the upper tunnel insulation layer, an intergate insulation layer disposed on the floating gate, and a control gate disposed on the intergate insulation layer.

The lower tunnel insulation layer may be a crystalline silicon oxide layer. The upper tunnel insulation layer may be a silicon oxide layer. The upper tunnel insulation layer may be an amorphous silicon oxide layer. The floating gate and the control gate may include conductive polycrystalline silicon. The intergate insulation layer may extend along side surfaces of the lower tunnel insulation layer, the upper tunnel insulation layer, and the floating gate, and at least one end of the intergate insulation layer contacts the substrate. The control gate may be disposed on a top surface and side surfaces of the intergate insulation layer, and is separated from the substrate. The memory device may include a capping layer disposed on a top surface and side surfaces of the control gate and the side surfaces of the intergate insulation layer. The capping layer may include silicon oxide and may have a uniform thickness. The memory device may include an amorphous silicon layer formed between the lower tunnel insulation layer and the upper tunnel insulation layer.

At least one of the above and other features and advantages of the present invention may be separately realized by providing a flash memory device, including a lower tunnel insulation layer disposed on a substrate, an upper tunnel insulation layer disposed on the lower tunnel insulation layer, a charge trap insulation layer disposed on the upper tunnel insulation layer, a blocking layer disposed on the charge trap insulation layer, a gate electrode disposed on the blocking layer, and a dielectric capping layer disposed on the gate electrode.

The charge trap insulation layer may include a silicon nitride layer. The blocking layer may include aluminum oxide.

At least one of the above and other features and advantages of the present invention may be separately realized by providing a method of fabricating a flash memory device, the method including forming a lower tunnel insulation layer on a substrate, forming an amorphous silicon layer on the lower tunnel insulation layer, forming an upper tunnel insulation layer on the amorphous silicon layer, forming a floating gate on the upper tunnel insulation layer, forming an intergate insulation layer on the floating gate, and forming a control gate on the intergate insulation layer.

Forming the lower tunnel insulation layer may include thermally oxidizing a surface of the substrate. The amorphous silicon layer may include forming the amorphous silicon layer using Si3H8 gas. Forming the upper tunnel insulation layer may include oxidizing amorphous silicon. The floating gate and the control gate may be formed of conductive polycrystalline silicon. The method may include forming an intermediate tunnel insulation layer on the lower tunnel insulation layer before forming the upper tunnel insulation layer. Forming the intermediate tunnel insulation layer may include forming an amorphous silicon layer.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIGS. 1A and 1B illustrate cross-sectional views of a first exemplary embodiment of a unit cell including an exemplary multilayer tunnel insulator employable by a flash memory device;

FIGS. 2A and 2B illustrate cross-sectional views of a second exemplary embodiment of a unit cell 200 including another exemplary multilayer tunnel insulator employing one or more aspects of the present invention;

FIG. 3 illustrates a cross-sectional view of a SONOS- or TANOS-type CTF memory device, as an exemplary device, employing the first exemplary embodiment of the tunnel insulator shown in FIGS. 1A and 1B;

FIG. 4 illustrates a cross-sectional view, along an XZ plane, of a SONOS- or TANOS-type CTF memory device, as an exemplary device, employing the second exemplary embodiment of the tunnel insulator shown in FIGS. 2A and 2B;

FIGS. 5A-8B illustrate cross-sectional views of resulting structures obtained during an exemplary method of fabricating a flash memory device employing the exemplary multilayer tunnel structure illustrated in FIGS. 1A and 1B;

FIGS. 9 and 10 illustrate cross-sectional views of resulting structures obtained during an exemplary method of fabricating a flash memory device employing the exemplary multilayer tunnel structure illustrated in FIGS. 2A and 2B;

FIG. 11 illustrates a graph of a relationship between erasing tunneling effect measurement results obtained from a memory device employing one or more aspects of the present invention and erasing tunneling effect measurement results of a memory device employing a conventional tunnel insulator;

FIG. 12 illustrates a graph of a relationship between electrical thickness measurement results of multilayer tunnel insulators according to exemplary embodiments of the present invention and electrical thickness measurement results of a conventional single-layer tunnel insulator; and

FIG. 13 illustrates a graph of a relationship between erase voltage property measurement results of multilayer tunnel insulators according to exemplary embodiments of the present invention and erase voltage property measurement results of a conventional single-layer tunnel insulator.

### DETAILED DESCRIPTION OF THE INVENTION

Korean Patent Application No. 10-2006-0093524 filed on Sep. 26, 2006, in the Korean Intellectual Property Office, and entitled: “Flash Memory Device Including Multilayer Tunnel Insulator and Method of Fabricating the Same,” is incorporated herein by reference in its entirety.

The invention will now be described more fully hereinafter with reference to the accompanying drawings, in which exemplary embodiments of the present invention are illustrated. The invention may, however, be embodied in different forms and should not be construed as limited to the embodiments set forth herein. Rather, these embodiments are provided so that this disclosure will be thorough and complete, and will fully convey the scope of the present invention to those skilled in the art.

In the figures, the dimensions of layers and regions may be exaggerated for clarity of illustration. It will also be understood that when a layer or element is referred to as being “on” another layer or element, it can be directly on the other layer or element, or intervening layers may also be present. Further, it will be understood that when a layer is referred to as being “under” another layer or element, it can be directly under, and one or more intervening layers or elements may also be present. In addition, it will also be understood that when a layer or element is referred to as being “between” two layers or elements, it can be the only layer between the two layers or elements, or one or more intervening layers or elements may also be present. Like reference numerals refer to like elements throughout.

The invention will now be described more fully with reference to the accompanying drawings, in which exemplary embodiments of the present invention are shown. The invention may, however, be embodied in many different forms and should not be construed as being limited to the embodiments set forth herein; rather, these embodiments are provided so that this disclosure will be thorough and complete, and will fully convey the concept of the present invention to those skilled in the art. In the drawings, the thicknesses of films or regions may be exaggerated for clarity. Like reference numerals in the drawings denote like elements, and thus their description will be omitted.

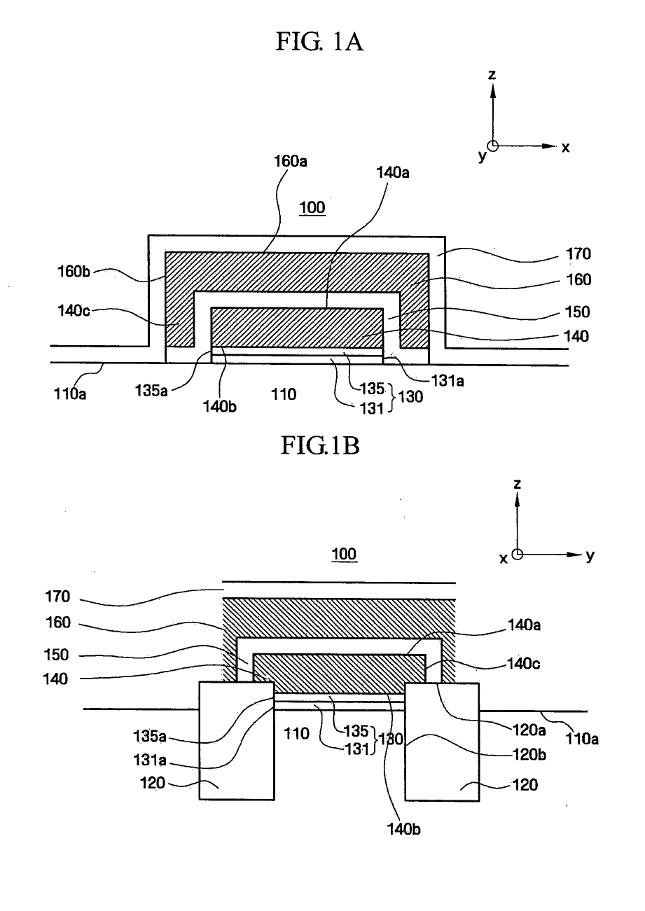

FIGS. 1A and 1B illustrate cross-sectional views of a first exemplary embodiment of a unit cell 100 employable by a flash memory device. Specifically, the cross-sectional view illustrated in FIG. 1A is taken along a XZ plane that extends along the X direction and the Z direction, and is perpendicular to a XY plane extending along the X direction and the Y direction, along which a substrate 110 of the unit cell 100 extends, and the cross-sectional view illustrated in FIG. 1B is taken along a YZ plane that extends along the Y and Z directions. The X direction may be perpendicular to the Y direction, and both the X direction and the Y direction may be perpendicular to the Z direction.

Referring to FIG. 1A, the unit cell 100 may include a tunnel insulator 130, including a lower tunnel insulation layer 131 and an upper tunnel insulation layer 135, a floating gate 140, an intergate insulation layer 150, a control gate 160, and a capping layer 170. The lower insulation layer 131 may be formed on the substrate 110, the upper tunnel insulation layer 135 may be formed on the lower tunnel insulator layer 131, the floating gate 140 may be formed on the upper tunnel insulation layer 135, the intergate insulation layer 150 may be formed on the floating gate 150, the control gate 160 may be formed on the floating gate 150, and the capping layer 170 may cover an upper surface and side surfaces of the control gate 160, and may contact the substrate 110.

Referring to FIG. 1B, the lower and upper tunnel insulation layers 131 and 135 may extend between a pair of isolations 120. At least portions of upper surfaces 120a and/or side surfaces 120b of the isolations 120 may contact portions, e.g., end portions, of the floating gate 140, portions of the intergate insulation layer 150, and/or portions of the control gate 160. In embodiments of the present invention, the isolations 120 may be shallow trench isolations that protrude beyond an upper surface 110a of the substrate 110.

The substrate 110 may be any substrate used in the manufacture of a semiconductor device. For example, the substrate 110 may be a silicon substrate. At least the upper surface 110a of the substrate 110 may include monocrystalline silicon.

The lower tunnel insulation layer 131 may be a crystalline silicon oxide layer. The lower tunnel insulation layer 131 may be formed by thermally oxidizing the upper surface 110a of the substrate 110. For example, if the upper surface 110a of the substrate 110 is formed of monocrystalline silicon, the lower tunnel insulation layer 131 may be a silicon oxide layer that is formed by oxidizing monocrystalline silicon. The lower tunnel insulation layer 131 may extend between and contact portions of the intergate insulation layer 150 along the X direction, and may extend between and contact the isolations 120 along the Y direction.

In embodiments of the present invention, the upper tunnel insulation layer 135 may include a silicon oxide layer and, more particularly, an amorphous silicon oxide layer. The upper tunnel insulation layer 135 may extend between and contact the intergate insulation layer 150 along the X direction, and may extend between and contact the isolations 120 along the Y direction.

In embodiments of the present invention, the upper tunnel insulation layer 135 may have a larger energy band gap than the lower tunnel insulation layer 131 or a polycrystalline silicon oxide layer. For example, in embodiments in which the upper tunnel insulation layer 135 is an amorphous silicon oxide layer and the lower tunnel insulation layer 131 is a monocrystalline silicon oxide layer, the upper tunnel insulation layer 135 may have a larger energy band gap than the lower tunnel insulation layer 131. More particularly, in embodiments in which the upper tunnel insulation layer 135 is an amorphous silicon oxide layer, the upper tunnel insulation layer 135 may have an energy band gap that is about 0.15 eV larger than an energy band gap of a moncrystalline silicon oxide layer or an energy band gap of a polycrystalline silicon oxide layer. In embodiments of the present invention, by providing an upper tunnel insulation layer 135 having a larger energy band gap than a monocrystalline or polycrystalline silicon oxide layer, it is possible to improve the information retention capabilities of electrically erasable programmable read only memories (EEPROMs) or flash memories, and enhance the tunneling properties of electrons.

In the exemplary embodiment illustrated in FIG. 1B, a combined thickness of the lower and upper tunnel insulation layers 131 and 135 along the Z direction may be smaller than a distance, along the Z direction, that the isolations 120 protrude beyond the upper surface 110a of the substrate 110. However, in embodiments of the present invention, a tunnel insulator 130 including the lower and upper tunnel insulation layers 131 and 135 may be formed to extend further from the upper surface 110a of the substrate 110 along the X direction than the isolations 120, i.e., as high as or even higher than the isolations 120.

The floating gate 140 may include a conductive material capable of storing information. For example, the floating gate 140 may include polycrystalline silicon having conductivity. At least portions of the upper surfaces 120a and/or the lateral surfaces 120b of the isolations 120 may contact portions, e.g., end portions, of the floating gate 140. Referring to FIG. 1B, an upper portion of the floating gate 140 may at least partially overlap the isolations 120 along the Y direction such that the floating gate 140 may have stepped shaped sides extending along the Z direction. In such embodiments, e.g., exemplary embodiment illustrated in FIGS. 1A and 1B, an area of an upper surface 140a of the floating gate 140 may be larger than an area of a lower surface 140b of the floating gate 140.

The intergate insulation layer 150 may electrically insulate the floating gate 140 from another conductive material, e.g., the control gate 160. In embodiments of the present invention, the intergate insulation layer 150 may include, e.g., three layers, such as a silicon oxide layer, a silicon nitride layer, and a silicon oxide layer, or a single material as a single layer. The intergate insulation layer 150 may cover the upper surface 140a and side surfaces 140c of the floating gate 140. For example, the intergate insulation layer 150 together with the substrate 110, the isolations 120 and/or the tunnel insulator 130 may surround the floating gate 140. Respective portions of the intergate insulation layer 150 may extend along a side surface 131a of the lower insulation layer 131 and a side surface 135a of the upper tunnel insulation layer extending along the Z direction. The intergate insulation layer 150 may extend along the upper surfaces 120a of the isolations 120.

As shown in FIG. 1A, a portion of the intergate insulation layer 150 may contact the substrate 110. Although FIG. 1A illustrates a portion of the intergate insulation layer 150 contacting the substrate 110 and extending along the X direction away from the tunnel insulator 130, the intergate insulation layer 150 may not extend along the upper surface 110a the substrate 110. That is, a thickness along the X direction of the portion(s) of the intergate insulation layer 150 contacting the substrate 110 and a thickness along the X direction of the portion(s) of the intergate insulation layer 150 extending along the Z direction and overlapping the side(s) 140c of the floating gate 140 and/or the sides 131a, 135a of the lower and upper tunnel insulation layers 131,135 may be substantially the same.

The control gate 160 may include a conductive material. For example, the control gate 160 may include polysilicon silicon having conductivity. The control gate 160 may be formed on the intergate insulation layer 150 and/or portions of the substrate 110. More particularly, e.g., the control gate 160 may be formed on portions of the intergate insulation layer 150 overlapping the upper surface 140a and/or the sides 140c of the floating gate 140 and/or contacting the substrate 110, and/or on portions of the intergate insulation layer 150 overlapping the sides 131a, 135a of the lower and upper tunnel insulation layers 131, 135. The control gate 160 may not directly contact the substrate 110 and, thus, e.g., in embodiments of the present invention, the control gate 160 may only extend on the upper surface 140a of the control gate 140.

The capping layer 170 may include silicon oxide. The capping layer 170 may cover an upper surface 160a and side surfaces 160b of the control gate 160. The capping layer 170 may contact portions of the intergate insulation layer 150, e.g., portions of the intergate insulation layer 150 extending along the X direction away from the tunnel insulation layer 130 and/or portions of the substrate 110. The capping layer 170 may have a uniform thickness along an entire length thereof, irrespective of directions along which particular portions thereof may extend, e.g., along the Z direction along the sides 160b of the control gate, along the Y direction along the upper surface 160a of the control gate. The capping layer 170 together with the substrate 110 may surround the control gate 160, the intergate insulation layer 150, the floating gate 140 and the tunnel insulation layer 130.

The tunnel insulator 130 employing one or more aspects of the present invention may be employed, e.g., in various types of memory devices. For example, the unit cell 100 shown in FIG. 1A may be, e.g., a charge trap flash (CTF) memory device. In such cases, the tunnel insulator 130 may serve as a lower insulation layer. In general, a CTF memory device may include a silicon-oxide-nitride-oxide-silicon (SONOS) structure, and the tunnel insulation 130 may serve as a lower oxide layer of such a CTF memory device. If the unit cell 110 shown in FIG. 1A corresponds to a flash memory device having a tantalum oxide-aluminum oxide-nitride-oxide-silicon (TANOS) structure, the tunnel insulator 130 may also serve as a lower oxide layer. Generally, the TANOS structure may include a silicon nitride layer (nitride), a silicon oxide layer (oxide), and a silicon substrate (silicon). The SONOS structure and the TANOS structure are well known to one of ordinary skill in the art to which one or more aspects of the present invention pertains, and thus, detailed descriptions thereof will be omitted.

Factors that may be used to determine properties of the tunnel insulator 130 may include the thickness and energy band gap of the tunnel insulator 130. Operations for storing information in the floating gate 140, e.g., a program operation or an erase operation, may generally be performed at a higher electric potential difference than a read operation, and an erase operation may be performed at a higher electric potential difference than a program operation. For example, a read operation may be performed at a voltage of about 2 V to about 5 V, and program and/or erase operations may be performed at a voltage of about 12 V to about 18 V. One of the operating voltages of program and erase operations may be a negative voltage. A voltage that is needed for retaining information may be lower than the operating voltage of a read operation. Accordingly, the tunnel insulator 130 may be required to facilitate tunneling at relatively high voltages, and provide excellent information retention capabilities at low voltages.

In embodiments of the present invention, the tunnel insulator 130 may have a larger energy band gap than a conventional single-layer tunnel insulator, and/or may be thicker than a conventional single-layer tunnel insulator. Therefore, embodiments of the present invention may provide flash memory devices having improved information retention capabilities at low voltages.

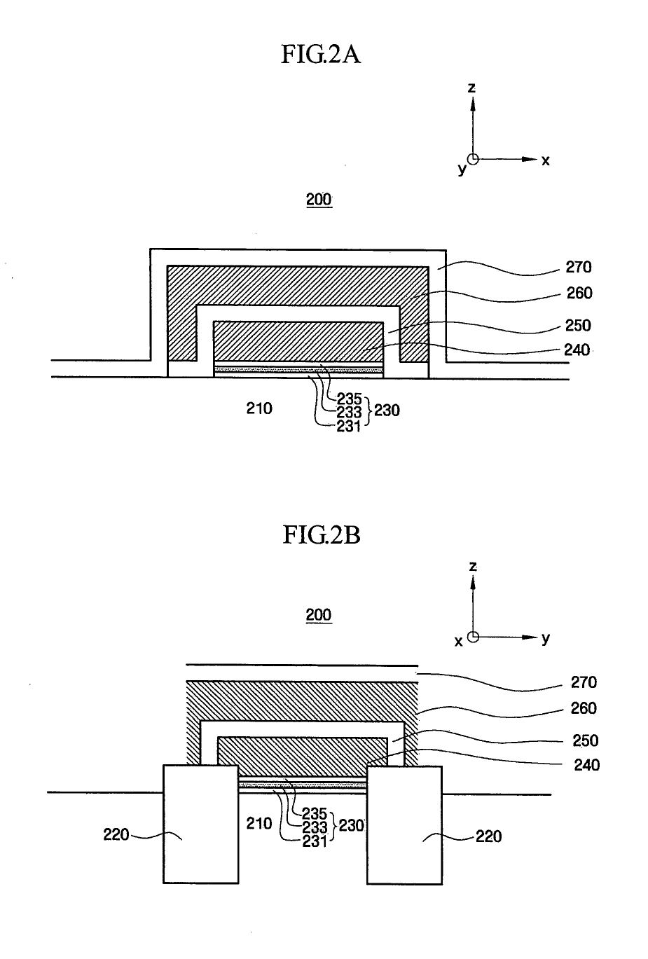

FIGS. 2A and 2B illustrate cross-sectional views of a second exemplary embodiment of a unit cell 200 employing one or more aspects of the present invention. In general, only differences between the exemplary embodiment illustrated in FIGS. 1A and 1B and the exemplary embodiment illustrated in FIGS. 2A and 2B will be described below. Referring to FIGS. 2A and 2B, the unit cell 200 may include a tunnel insulator 230. The tunnel insulator 230 may include three or more layers. For example, the tunnel insulator 230 may include a lower tunnel insulation layer 231, an upper tunnel insulation layer 235, and an intermediate tunnel insulation layer 233. The intermediate tunnel insulation layer 233 may be interposed between the lower tunnel insulation layer 231 and the upper tunnel insulation layer 235.

The lower tunnel insulation layer 231 and the upper tunnel insulation layer 235 may substantially correspond to the lower insulation layer 131 and the upper insulation layer 135 described above in reference to FIGS. 1A and 1B. The lower tunnel insulation layer 231 may be formed on a substrate 210, and the upper tunnel insulation layer 235 may be formed on the lower tunnel insulation layer 231.

The intermediate tunnel insulation layer 233 may include amorphous silicon. For example, the intermediate tunnel insulation layer 233 may include amorphous silicon with no impurities implanted thereinto. Fermi levels of the lower and upper insulation layers 231 and 235 may be in the valence band of an energy band, and a Fermi level of the intermediate tunnel insulation layer 233 may be between the valance band and a conduction band. Accordingly, the intermediate tunnel insulator 233 may serve as an insulation layer in the absence of a bias voltage, and may perform almost the same functions as a conductive material, i.e., may perform lower-resistance operations than an insulation layer, during a tunneling operation. Therefore, embodiments of the present invention including the tunnel insulator 230 may provide better tunneling properties than a conventional single-layer tunnel insulator. In embodiments of the present invention, the tunnel insulator 230 may be thicker than a conventional single-layer tunnel insulator, and thus, devices employing the tunnel insulator 230 may be easier to manufacture than devices employing a conventional single-layer tunnel insulator. Flash memory devices employing the upper tunnel insulator 235 having a relatively large energy band gap, according to one or more aspects of the present invention, may have improved information retention capabilities.

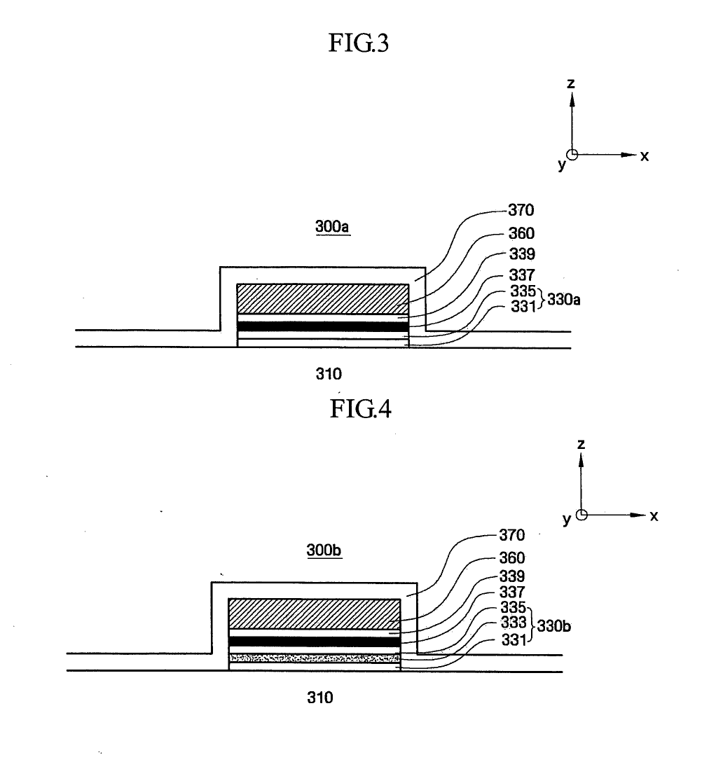

FIG. 3 illustrates a cross-sectional view, along an XZ plane, of a SONOS- or TANOS-type CTF memory device 300a employing the first exemplary embodiment of the tunnel insulator shown in FIGS. 1A and 1B. Referring to FIG. 3, the CTF memory device 300a may include a multilayer tunnel insulator 330a, a charge trap layer 337, a blocking layer 339, a gate electrode 360 and a dielectric capping layer 370. The multilayer tunnel insulator 330a may be on a substrate 310, the charge trap layer 337 may be on the multilayer tunnel insulator 330a, the blocking layer 339 may be on the charge trap layer 337, the gate electrode 360 may be on the blocking layer 339, and the dielectric capping layer 370 may be on the gate electrode 360.

The multilayer tunnel insulator 330a may correspond to the multilayer tunnel insulator 130 of FIGS. 1A and 1B, and may include a lower tunnel insulation layer 331 and an upper tunnel insulation layer 335. The upper tunnel insulation layer 335 may be on the lower tunnel insulation layer 331. The lower tunnel insulation layer 331 and the upper tunnel insulation 335 correspond to the lower tunnel insulation layer 131 and the upper tunnel insulation layer 331 and the lower tunnel insulation layer 335, respectively, of the first exemplary embodiment illustrated in FIGS. 1A and 1B.

The charge trap layer 337 may include a silicon nitride layer, and the blocking layer 339 may include a silicon oxide layer. Charge trap layers and blocking layers are well known to one of ordinary skill in the art to which one or more aspects of the present invention pertains, and thus, detailed descriptions of the charge trap layer 337 and the blocking layer 339 will not be provided.

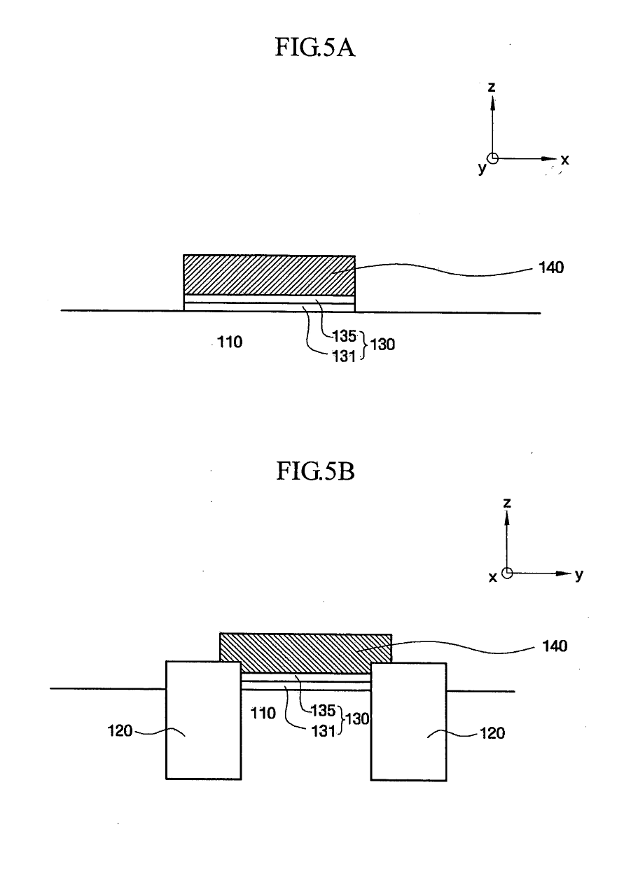

FIG. 4 illustrates a cross-sectional view, along an XZ plane, of a SONOS- or TANOS-type CTF memory device 300b employing the second exemplary embodiment of the tunnel insulator shown in FIGS. 2A and 2B. Referring to FIG. 4, the CTF memory device 300b may include a multilayer tunnel insulator 330b, a charge trap layer 337, a blocking layer 339, a gate electrode 360, and a dielectric capping layer 370. The multilayer tunnel insulator 330b may be on a substrate 310, the charge trap layer 337 may be on the multilayer tunnel insulator 330b, the blocking layer 339 may be on the charge trap layer 337, the gate electrode 360 may be on the blocking layer 339, and the dielectric capping layer 370 may be on the gate electrode 360.

The multilayer tunnel insulator 330b may correspond to the multilayer tunnel insulator 230 of FIGS. 2A and 2B, and may include a lower tunnel insulation layer 331, an intermediate tunnel insulation layer 333, and an upper insulation layer 335. The intermediate tunnel insulation layer 333 may be on the lower tunnel insulation layer 331, and the upper tunnel insulation layer 335 may be on the intermediate tunnel insulation layer 333. The lower, intermediate and upper insulation layers 331, 333 and 335 correspond to the lower, intermediate and upper insulation layers 231, 233 and 235 of FIGS. 2A and 2B.

The tunnel insulators 130, 230, 330a, and 330b may be physically thicker than a conventional single-layer tunnel insulator, but may be electrically thinner than a conventional single-layer tunnel insulator. Because the tunnel insulators 130, 230, 330a, and 330b may be electrically thinner than a conventional single-layer tunnel insulator, the tunnel insulators 130, 230, 330a, and 330b may provide better tunneling properties than a conventional single-layer tunnel insulator. Memory devices employing one or more of the tunnel insulators 130, 230, 330a, and 330b, which may have a higher energy barrier than a conventional single-layer tunnel insulator, may have improved information retention capabilities than a conventional single-layer tunnel insulator.

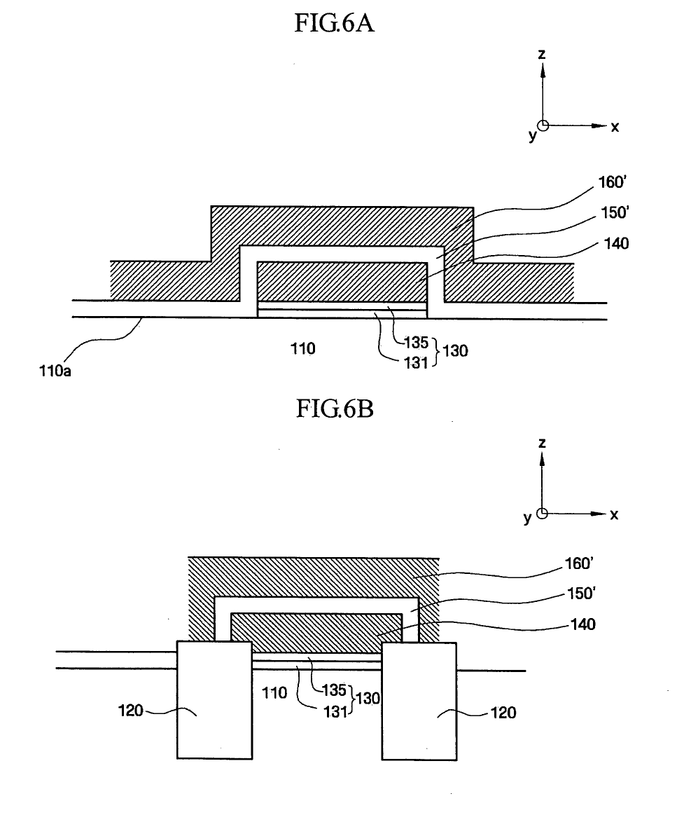

A method of fabricating an exemplary flash memory device according to an exemplary embodiment of the present invention will hereinafter be described in detail. FIGS. 5A-8B illustrate cross-sectional views of resulting structures obtained during an exemplary method of fabricating a flash memory device employing the exemplary embodiment of the multilayer tunnel structure 130 illustrated in FIGS. 1A and 1B. More particularly, FIGS. 5A, 6A, 7A and 8A illustrate cross-sectional views of the exemplary flash memory device along an XZ plane, and FIGS. 5B, 6B, 7B and 8B illustrate cross-sectional views of the exemplary flash memory device along the YZ plane.

Referring to FIGS. 5A-8B, the isolations 120, the lower tunnel insulation layer 131, the upper tunnel insulation layer 135, and the floating gate 140 may be formed on the substrate 110. More particularly, in embodiments of the present invention, the tunnel insulator 130, including the lower tunnel insulation layer 131 and the upper tunnel insulation layer 135 may be formed on the substrate 110 before the isolations 120 are formed.

Referring to FIG. 5A, the lower tunnel insulation layer 131 may be formed on the substrate 110 using, e.g., thermal oxidation. Because the surface, e.g., the upper surface 110a, of the substrate 110 may be formed of monocrystalline silicon, the lower tunnel insulation layer 131 may be a silicon oxide layer, which may be formed by, e.g., oxidizing the monocrystalline silicon of the substrate 110. The lower tunnel insulation layer 131 may be formed on the substrate 110. In embodiments of the present invention, the lower tunnel insulation layer 131 may be formed to a thickness of about 30 Å to about 50 Å, and/or may be formed by, e.g., injecting H₂O or O₂ gas and heating the substrate 110 to a temperature of about 900° C. so that the upper surface 110a of the substrate 110 may be oxidized. In embodiments of the present invention, the thermal oxidation method may be a radical oxidation method. Radical oxidation methods are well known to one of ordinary skill in the art to which one or more aspects of the present invention pertains, and, thus, a detailed description of the radical oxidation methods has been omitted.

The upper tunnel insulation layer 135 may be formed by providing an amorphous silicon layer on the lower tunnel insulation layer 131, and thermally oxidizing the amorphous silicon layer. Accordingly, the upper tunnel insulation layer 135 may be a silicon oxide layer that may be formed by, e.g., oxidizing amorphous silicon. The upper tunnel insulation layer 135 may be formed to a thickness of about 30 Å to about 100 Å. More particularly, e.g., the amorphous silicon layer of the may be formed using Si₃H₈ gas as a source gas and using an atomic layer deposition (ALD)-like method. In embodiments of the present invention, the amorphous silicon layer may be thinly formed using, e.g., a low pressure-chemical vapor deposition (LP-CVD) method.

Referring to FIG. 5B, after forming the tunnel insulator 130, the isolations 120 may be formed. The isolations 120 may be formed by, e.g., forming a silicon nitride layer (not shown) on the tunnel insulator 130, performing a photolithography operation so that trenches may be formed, filling the trenches with a dielectric material, and performing a chemical mechanical polishing (CMP) operation so that the tunnel insulation layer 130 may be separated by isolations 120. As a result of the CMP operation, a thickness of the tunnel insulator 130 along the Z direction may be less than the distance, along the Z direction, that the isolations 120 protrude beyond the upper surface 110a of the substrate 110, as illustrated in FIG. 5B. However, in embodiments of the present invention, the tunnel insulator 130 may be formed to be as tall, e.g., thickness of the tunnel insulator 130 and distance that isolations 120 protrude beyond the upper surface 110a may be substantially the same. For example, the isolations 120 may be formed by forming a buffer layer (not shown), e.g., a silicon layer, on the tunnel insulator 130 and forming a silicon nitride layer on the buffer layer, and in such cases, e.g., the tunnel insulator 130 may be as tall as the isolations 120, and this is within the scope of the present invention.

Thereafter, a conductive layer may be formed, and a photolithography operation may be performed, thereby forming the floating gate 140, so that separate floating gates 140 may be provided for each unit cell. The floating gate 140 may be formed, e.g., of conductive polycrystalline silicon. The conductive floating gate 140 may be formed by forming a polycrystalline silicon layer, forming a buffer layer (not shown), e.g., a silicon oxide layer, on the polycrystalline silicon layer, and implanting, e.g., P or As ions. The buffer layer may be removed before or after formation of the floating gate 140. For example, the conductive layer employed for forming the floating gate 140 may be formed by providing a monocrystalline silicon layer and annealing the monocrystalline silicon layer at a temperature of about 800° C. so that the monocrystalline silicon layer may be transformed into a polycrystalline silicon layer.

Referring to FIGS. 6A and 6B, an insulation layer 150′ for forming the intergate insulation layer 150 may be formed on the upper surface 110a, e.g., the entire upper surface 110a, of the substrate 110, and a conductive layer 160′ for forming the control gate 160 may be formed on the insulation layer 150′.

In embodiments of the present invention, the insulation layer 150′ may be formed, e.g., as a triple layer including a silicon oxide layer, a silicon nitride layer, and a silicon oxide layer. In such cases, a silicon oxide layer may be formed on the upper surface 110a of the substrate 110, e.g., on the substrate 110, the isolation 120 and/or the upper tunnel insulation layer 135, a silicon nitride layer may be formed on the silicon oxide layer, and a silicon oxide layer may be formed on the silicon nitride layer, thereby forming the insulation layer 150′. An intergate insulation layer 150 formed in such a manner may effectively trap electrons, and thus, may be employed by a CTF memory device. The insulation layer 150′ may be formed using a deposition method, e.g., a CVD method.

In embodiments of the present invention, to form the control gate 150, the conductive layer 160′ may then be formed on the upper surface 110a of the substrate 110, e.g., on insulation layer 150′ formed on the substrate 110. The conductive layer 160′ may be formed of, e.g., conductive polycrystalline silicon, as a metal silicide layer or a metallic layer.

Referring to FIGS. 7A and 7B, the intergate insulation layer 150 and the control gate 160 may be formed by performing a photolithography operation. The intergate insulation layer 150 may separated along the X and Y directions, such that a separate intergate insulation layer 150 may be provided for each of the unit cells. However, in embodiments of the present invention, the intergate insulation layer 150 may not be separated for each of the unit cells along the Y direction. The control gate 160 may be formed to be separate in each unit cell along the X direction, and to extend along the Y direction, rather than being separated for each of the unit cells along the X direction. Formation of insulation layers and control gates by photolithography is well known to one of ordinary skill in the art to which one or more aspects of the present invention pertains, and thus, a detailed description of a process of forming the intergate insulation layer 150 and the control gate 160 may be omitted.

Referring to FIGS. 8A and 8B, the capping layer 170 may be formed on the control gate 160. In embodiments of the present invention, the capping layer 170 may include a silicon oxide layer. As shown in FIG. 8A, the capping layer 170 may be formed to contact the upper surface 160a and the sides 160b of the control gate 160 and portions of the upper surface 110a of the substrate 110 along the X direction, and, as shown in FIG. 8B, may cover the upper surface 160a of the control gate 160 along the Y direction. The capping layer 170 may be formed using a deposition method.

Thereafter, a silicon nitride layer (not shown) may be formed on the capping layer 170. Then, contacts, signal lines, and/or vias for signal transmission may be formed, thereby completing the exemplary formation of a flash memory device.

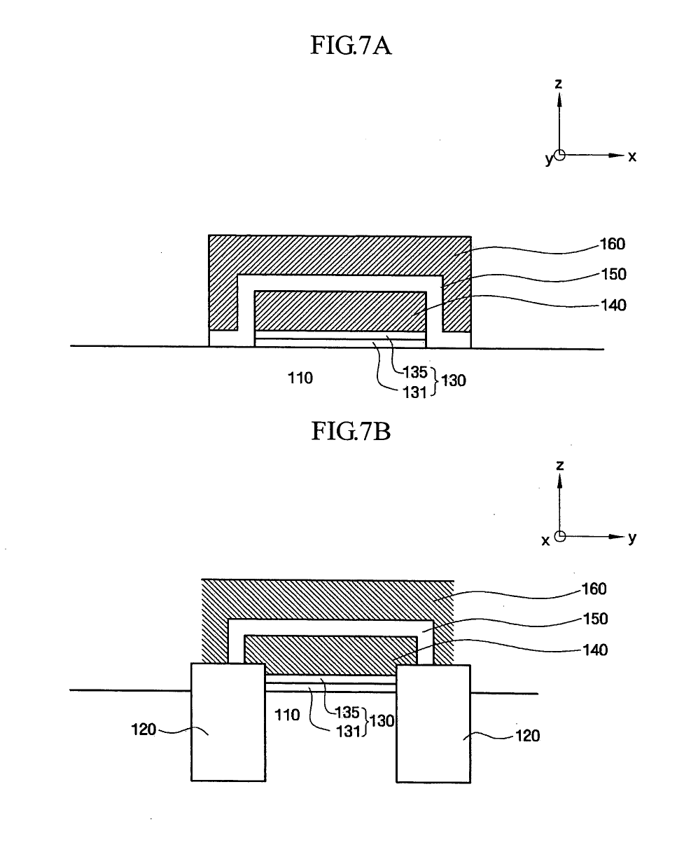

A method of fabricating an exemplary flash memory device according to a second exemplary embodiment of the present invention will hereinafter be described. FIGS. 9 and 10 illustrate cross-sectional views of resulting structures obtained during an exemplary method of fabricating a flash memory device employing the exemplary multilayer tunnel structure illustrated in FIGS. 2A and 2B.

Referring to FIG. 9, an insulation layer 231 a for forming the lower tunnel insulation layer 231 may be formed on the substrate 210, and an amorphous silicon layer 233a for forming the intermediate tunnel insulation layer 233 may be formed on the insulation layer 231a. In embodiments of the present invention, the amorphous silicon layer 233a may be thicker than the insulation layer 231a. The insulation layer 231a may be formed by oxidizing the substrate 210. The amorphous silicon layer 233a may be formed using a Si₃H₈ gas as a source gas, and using an ALD-like method. Referring to FIG. 9, an insulation layer 235a for forming the upper tunnel insulation layer 235 may be formed by thermally oxidizing a surface of the amorphous silicon layer 233a. More particularly, e.g., the amorphous silicon layer 233a may be thermally oxidized for a predetermined amount of time, to complete formation of the exemplary tunnel insulator 230, as a triple layer structure. Oxidizing an amorphous silicon layer is well known to one of ordinary skill in the art to which one or more aspects of the present invention pertains, and may involve a variety of processing conditions (e.g., temperature). Thus, a detailed description of the oxidization of the amorphous silicon layer 233a will be omitted. It will be also understood by persons of ordinary skill in the art to which one or more aspects of the present invention pertains that a thickness of each layer of the tunnel insulator 230 may be altered in various manners.

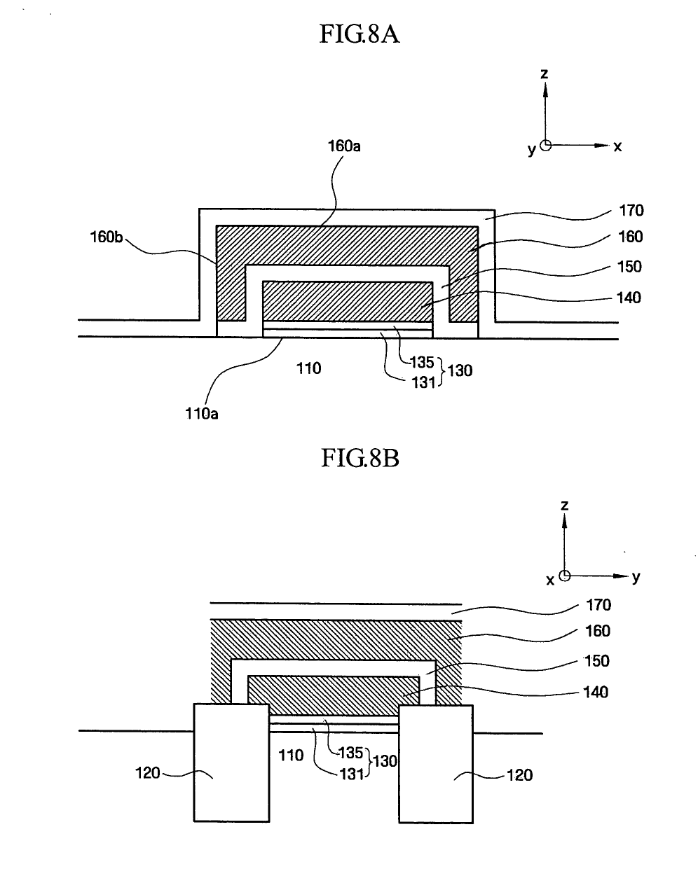

Embodiments of the present invention provide memory devices having improved properties relative to conventional memory devices. FIGS. 11, 12 and 13 illustrate some of the advantageous effects that may be obtained by employing one or more aspects of the present invention.

FIG. 11 illustrates a graph of a relationship between erasing tunneling effect measurement results obtained from a memory device employing one or more aspects of the present invention and erasing tunneling effect measurement results of a memory device employing a conventional tunnel insulator. Referring to FIG. 11, the X axis represents a tunneling voltage V_{E}, the Y axis represents a tunneling current I_{E}, and reference characters A, B, C, and D correspond to the memory device employing one or more aspects of the present invention.

More particularly, reference character A corresponds to a multilayer tunnel insulator having a total thickness of 90 Å, which includes lower, intermediate, and upper tunnel insulation layers respectively having thicknesses of 32 Å, 26 Å, and 32 Å. Reference character B corresponds to a multilayer tunnel insulator having a total thickness of 110 Å, which includes lower, intermediate, and upper tunnel insulation layers respectively having thicknesses of 40 Å, 30 Å, and 40 Å. Reference character C corresponds to a multilayer tunnel insulator having a total thickness of 125 Å, which includes lower, intermediate, and upper tunnel insulation layers respectively having thicknesses of 45 Å, 35 Å, and 45 Å. Reference character D corresponds to a multilayer tunnel insulator having a complete thickness of 140 Å, which includes intermediate, and upper tunnel insulation layers respectively having thicknesses of 40 Å, 40 Å, and 60 Å.

The thickness of the conventional single-layer tunnel insulator was set to about 83 Å.

Referring to FIG. 11, for the same tunneling voltage, the multilayer tunnel insulators A, B, C, and D may provide higher tunneling currents than the conventional single-layer tunnel insulator. The multilayer tunnel insulators A, B, C, and D are thicker than the conventional single-layer tunnel insulator, and also provide better properties than the conventional single-layer tunnel insulator. That is, the multilayer tunnel insulators A, B, C, and D may achieve as high a tunneling current as the conventional single-layer tunnel insulator while being driven at a lower voltage than the conventional single-layer tunnel insulator, and thus, may reduce power consumption.

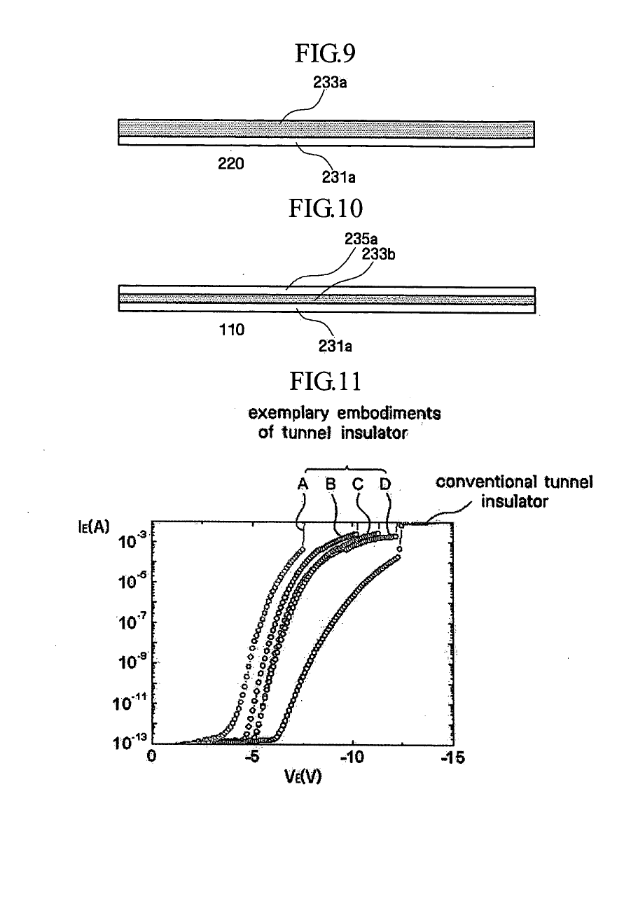

FIG. 12 illustrates a graph of a relationship between electrical thickness measurement results of the multilayer tunnel insulators A, B, C, and D according to exemplary embodiments of the present invention and electrical thickness measurement results of conventional single-layer tunnel insulators. Referring to FIG. 12, the X axis displays conventional single-layer tunnel insulators and the multilayer tunnel insulators A, B, C, and D according to exemplary embodiments of the present invention, and the Y axis represents electrical thickness, i.e., thickness-of-oxide Tₒₓ (Å).

Referring to FIG. 12, even though the multilayer tunnel insulators A, B, C, and D are physically thicker than conventional single-layer tunnel insulators, the multilayer tunnel insulators A, B, C, and D according to exemplary embodiments of the present invention are electrically thinner than conventional single-layer tunnel insulators. The electrical thickness of a tunnel insulator may be determined by measuring the capacitance of the tunnel insulator. The lower the capacitance of a tunnel insulator is, the greater the electrical thickness of the tunnel insulator becomes. On the contrary, the higher the capacitance of a tunnel insulator is, the lower the electrical thickness of the tunnel insulator becomes. Referring to FIG. 12, the lower the electrical thickness of a tunnel insulator becomes, the better the tunneling properties of the tunnel insulator become.

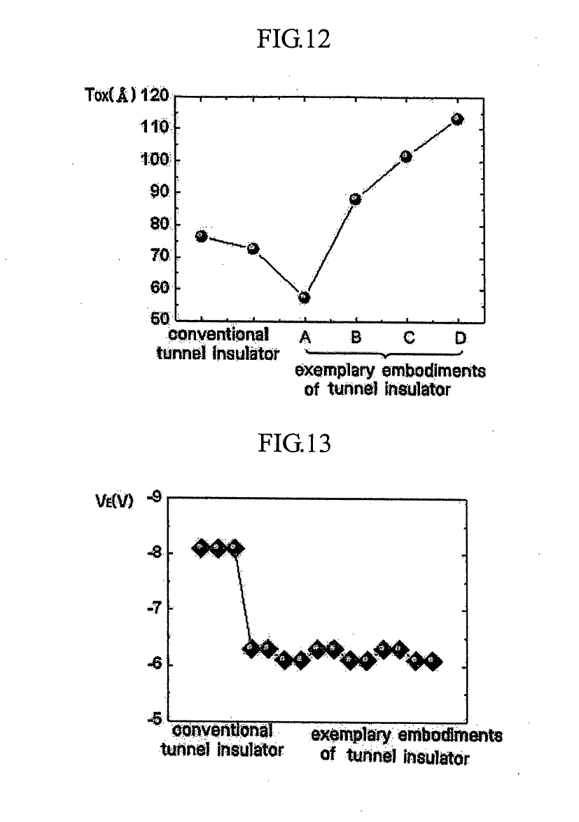

FIG. 13 illustrates a graph of a relationship between erase voltage property measurement results of multilayer tunnel insulators according to exemplary embodiments of the present invention and erase voltage property measurement results of conventional single-layer tunnel insulators. Referring to FIG. 13, the X axis displays tunnel insulators according to embodiments of the present invention and conventional single-layer tunnel insulators, and the Y axis represents a tunneling voltage V_{E} which is a voltage at which tunneling occurs i.e., an erase voltage.

In FIG. 13, the three dots from the far left indicate the erase voltage properties of conventional single-layer tunnel insulators, and the other dots indicate the erase voltage properties of multilayer tunnel insulators according to embodiments of the present invention. Referring to FIG. 13, erase voltages provided by multilayer tunnel insulators according to embodiments of the present invention are about 2V lower than erase voltages provided by conventional single-layer tunnel insulators. That is, multilayer tunnel insulators according to embodiments of the present invention may operate at lower erase voltages than conventional single-layer tunnel insulators. Accordingly, multilayer tunnel insulators employing one or more aspects of the present invention may provide better coupling properties and higher reliability and endurance than conventional single-layer tunnel insulators, while consuming less power than conventional single-layer tunnel insulators.

Experimental results show that multilayer tunnel insulators according to embodiments of the present invention may separately provide higher endurance than conventional tunnel insulators because program and erase operations may be performed at lower voltages in embodiments of the present invention than in conventional single-layer tunnel insulators. Thus, multilayer tunnel insulators according to embodiments of the present invention may be less affected than conventional single-layer tunnel insulators by physical stress.

Experimental results separately show that, even under hard conditions, multilayer tunnel insulators according to embodiments of the present invention provide better properties, including information retention properties, and maintain the improved properties for a longer period of time than conventional single-layer tunnel insulators.

As described above, the flash memory device including a multilayer tunnel insulator employing one or more aspects of the present invention may provide stable programming and erasing properties at program and erase voltages, respectively, and may provide stable information retention properties at an information retention voltage.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A flash memory device, comprising:
a lower tunnel insulation layer disposed on a substrate;
an upper tunnel insulation layer disposed on the lower tunnel insulation layer;
a floating gate disposed on the upper tunnel insulation layer;
an intergate insulation layer disposed on the floating gate; and
a control gate disposed on the intergate insulation layer.

2. The flash memory device as claimed in claim 1, wherein the lower tunnel insulation layer is a crystalline silicon oxide layer.

3. The flash memory device as claimed in claim 1, wherein the upper tunnel insulation layer is a silicon oxide layer.

4. The flash memory device as claimed in claim 1, wherein the upper tunnel insulation layer is an amorphous silicon oxide layer.

5. The flash memory device as claimed in claim 1, wherein the floating gate and the control gate include conductive polycrystalline silicon.

6. The flash memory device as claimed in claim 1, wherein the intergate insulation layer extends along side surfaces of the lower tunnel insulation layer, the upper tunnel insulation layer, and the floating gate, and at least one end of the intergate insulation layer contacts the substrate.

7. The flash memory device as claimed in claim 6, wherein the control gate is disposed on a top surface and side surfaces of the intergate insulation layer, and is separated from the substrate.

8. The flash memory device as claimed in claim 1, further comprising a capping layer disposed on a top surface and side surfaces of the control gate and the side surfaces of the intergate insulation layer.

9. The flash memory device as claimed in claim 8, wherein the capping layer includes silicon oxide and has a uniform thickness.

10. The flash memory device as claimed in claim 1, further comprising an amorphous silicon layer formed between the lower tunnel insulation layer and the upper tunnel insulation layer.

11. A flash memory device, comprising:
a lower tunnel insulation layer disposed on a substrate;
an upper tunnel insulation layer disposed on the lower tunnel insulation layer;
a charge trap insulation layer disposed on the upper tunnel insulation layer;
a blocking layer disposed on the charge trap insulation layer;
a gate electrode disposed on the blocking layer; and
a dielectric capping layer disposed on the gate electrode.

12. The flash memory device as claimed in claim 11, wherein the charge trap insulation layer comprises a silicon nitride layer.

13. The flash memory device as claimed in claim 11, wherein the blocking layer includes aluminum oxide.

14. A method of fabricating a flash memory device, the method comprising:
forming a lower tunnel insulation layer on a substrate;
forming an amorphous silicon layer on the lower tunnel insulation layer;
forming an upper tunnel insulation layer on the amorphous silicon layer;
forming a floating gate on the upper tunnel insulation layer;
forming an intergate insulation layer on the floating gate; and
forming a control gate on the intergate insulation layer.

15. The method as claimed in claim 14, wherein forming the lower tunnel insulation layer comprises thermally oxidizing a surface of the substrate.

16. The method as claimed in claim 14, wherein forming the amorphous silicon layer comprises forming the amorphous silicon layer using Si₃H₈ gas.

17. The method as claimed in claim 14, wherein forming the upper tunnel insulation layer comprises oxidizing amorphous silicon.

18. The method as claimed in claim 14, wherein the floating gate and the control gate are formed of conductive polycrystalline silicon.

19. The method as claimed in claim 14, further comprising forming an intermediate tunnel insulation layer on the lower tunnel insulation layer before forming the upper tunnel insulation layer.

20. The method as claimed in claim 19, wherein forming the intermediate tunnel insulation layer comprises forming an amorphous silicon layer.
